(19) United States
(12) Patent Application Publication
(10) Pub. No.: US 2015/0077605 A1
(43) Pub. Date: Mar. 19, 2015

(54) SOLID-STATE IMAGING APPARATUS, METHOD FOR DRIVING THE SAME, AND IMAGING SYSTEM

(71) Applicant: CANON KABUSHIKI KAISHA, Tokyo (JP)

(72) Inventors: Hideaki Takada, Yokohama-shi (JP); Toshiaki Ono, Ebina-shi (JP)

(21) Appl. No.: 14/470,141

(22) Filed: Aug. 27, 2014

(30) Foreign Application Priority Data
Sep. 13, 2013 (JP) 2013-191038

(51) Int. Cl. H04N 5/3745; H04N 5/357

(52) U.S. Cl. CPC H04N 5/3745; H04N 5/357
USPC 348/300

(57) ABSTRACT

A solid-state imaging apparatus improving a read-out speed and a noise-reduction rate comprises: a photoelectric conversion portion configured to convert light into an electric charge; a floating diffusion portion configured to convert the electric charge into a voltage; a transfer transistor configured to transfer the electric charge converted by the photoelectric conversion portion to the floating diffusion portion; an amplifying transistor configured to amplify the voltage of the floating diffusion portion; a selecting transistor configured to output the voltage amplified by the amplifying transistor to an output line; and a switch provided between the output line and a current source, wherein the selecting transistor and the switch are held at an OFF state, during a period of a transition of the transfer transistor from an OFF state to an ON state and during a period of a transition of the transfer transistor from the ON state to the OFF state.

### BACKGROUND OF THE INVENTION

1. Field of the Invention

The present invention relates to a solid-state imaging apparatus, a method for driving the same, and an imaging system.

2. Description of the Related Art

In recent years, solid-state imaging apparatuses are on a progressive trend toward greater numbers of pixels and larger sized areas, and there is such a tendency along with the trend that a parasitic capacitance of a vertical signal line which reads out a signal from a pixel increases. On the other hand, the solid-state imaging apparatuses are required to read out high-pixel signals such as full HD, 4K and 8K, at high speed.

In Japanese Patent Application Laid-Open No. 2000-4399, a source of an amplifying transistor of a pixel is connected to a vertical signal line, and a gate is connected to a reset potential through a reset transistor. Furthermore, Japanese Patent Application Laid-Open No. 2000-4399 discloses a method of resetting the vertical signal line at each of timing before a noise of the pixel is read out and timing before a pixel signal is read out.

The method in Japanese Patent Application Laid-Open No. 2000-4399 needs a time period (hereinafter referred to as charging/discharging time period) for charging or discharging the vertical signal line until the reset potential of the vertical signal line reaches potential of a pixel noise and the pixel signal, and accordingly has a problem in increasing the speed of reading out the pixel signal. In addition, if the reading out time period is shortened so as to increase the speed, there would be a difficulty in reading out the pixel noise and the pixel signal due to a large time constant of the vertical signal line, and accordingly would be a problem of lowering a noise reduction rate.

### SUMMARY OF THE INVENTION

According to an aspect of the present invention, a solid-state imaging apparatus comprises: a photoelectric conversion portion configured to converting light into an electric charge; a floating diffusion portion configured to convert the electric charge into a voltage; a transfer transistor configured to transfer the electric charge converted by the photoelectric conversion portion to the floating diffusion portion; an amplifying transistor configured to amplify the voltage of the floating diffusion portion; a selecting transistor configured to output the voltage amplified by the amplifying transistor to an output line; and a switch provided between the output line and a current source, wherein the selecting transistor and the switch are held at an OFF state, during a period of a transition of the transfer transistor from an OFF state to an ON state, and during a period of a transition of the transfer transistor from the ON state to the OFF state.

Further features of the present invention will become apparent from the following description of exemplary embodiments with reference to the attached drawings.

### BRIEF DESCRIPTION OF THE DRAWINGS

FIG. 1 is a view illustrating a configuration example of a solid-state imaging apparatus according to a first embodiment.

FIG. 2 is a circuit diagram illustrating a configuration example of a pixel.

FIG. 3 is a timing chart illustrating a driving method according to the first embodiment.

FIG. 4 is a circuit diagram illustrating a configuration example of an amplifier.

FIG. 5 is a view illustrating a configuration example of a solid-state imaging apparatus according to a second embodiment.

FIG. 6 is a timing chart illustrating a driving method according to the second embodiment.

FIG. 7 is a circuit diagram illustrating a configuration example of a ramp signal generator.

FIG. 8 is a view illustrating a configuration example of an imaging system.

### DESCRIPTION OF THE EMBODIMENTS

Preferred embodiments of the present invention will now be described in detail in accordance with the accompanying drawings.

### First Embodiment

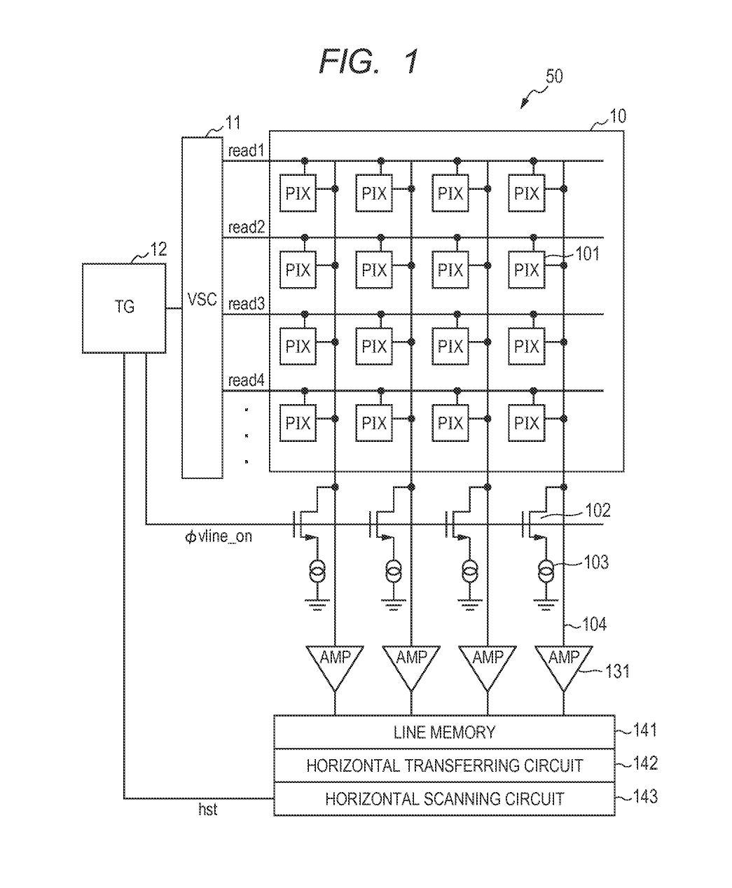

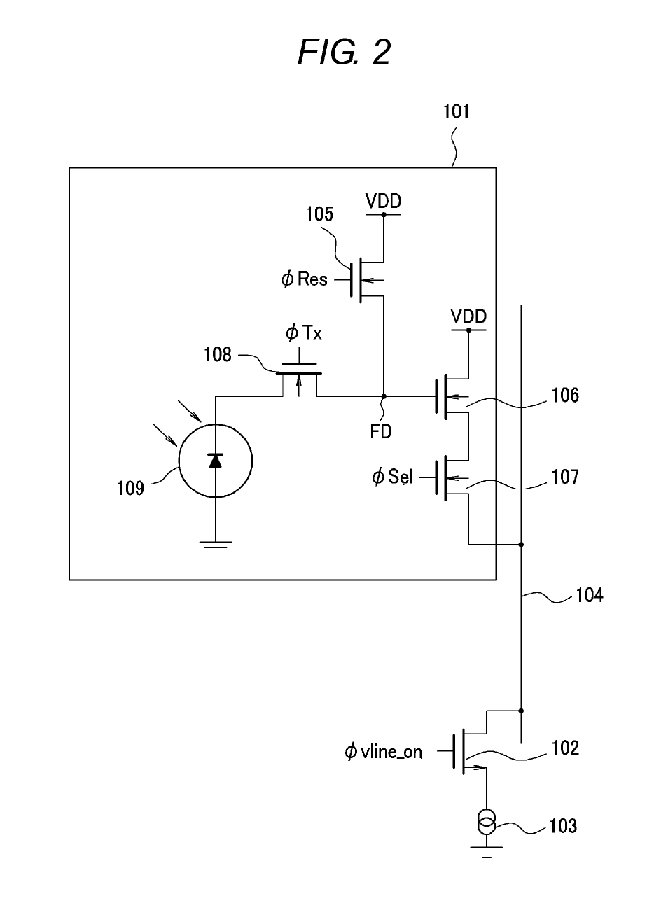

FIG. 1 is a view illustrating a configuration example of a solid-state imaging apparatus according to a first embodiment of the present invention. A solid-state imaging apparatus 50 has a pixel array 10, a vertical scanning circuit 11, a timing generator 12, a switch 102, a constant current source 103, a vertical output line 104, an amplifier 131, a line memory 141, a horizontal transferring circuit 142, and a horizontal scanning circuit 143. The pixel array 10 has a plurality of pixels 101 which are arranged in a two-dimensional matrix form. The pixel 101 converts incident light into an electric charge. The vertical scanning circuit 11 selects the plurality of pixels 101 successively row by row, through control lines read 1 to read 4 and the like. The pixel 101 that belongs to the selected row outputs a signal to the vertical output line 104 to which the pixel 101 is connected. The pixels 101 in each column out of the plurality of pixels 101 are each connected to the same vertical output line 104. The constant current source 103 that functions as the load means for an amplifying transistor 106 (FIG. 2) of the pixel 101, which will be described later, is connected to the vertical output line 104. The switch 102 is provided between the vertical output line 104 and the constant current source 103. In addition, the amplifiers 131 in each of the columns amplify signals of the vertical output lines 104 in each of the columns, and output the amplified signals, respectively. The line memory 141 holds the output signal of the amplifier 131 in each of the columns. The signals in each of the columns, which have been held by the line memory 141, are successively read out by the horizontal transferring circuit 142. The horizontal transferring circuit 142 is controlled by the scan of the horizontal scanning circuit 143. The timing generator 12 controls the switch 102 by a control signal φvline_on, and controls the horizontal scanning circuit 143 by a control signal hst.

FIG. 2 is a circuit diagram illustrating a configuration example of the pixel 101 in FIG. 1. The pixel 101 has a photoelectric conversion portion 109, a transfer transistor 108, a reset transistor 105, an amplifying transistor 106 and a row selecting transistor 107. Control voltages φTx, φRes and φSel are supplied by the vertical scanning circuit 11 in FIG. 1. The photoelectric conversion portion 109 is, for instance, a photodiode; and converts incident light into an electric charge and accumulates the electric charge therein. The transfer transistor 108 transfers the electric charge in the photoelectric conversion portion 109 to a floating diffusion portion FD, when the control voltage φTx becomes a high level. The floating diffusion portion FD converts the electric charge into voltage. The reset transistor 105 resets the floating diffusion portion FD to a power source potential VDD, when the control voltage φRes becomes a high level. The amplifying transistor 106 amplifies the voltage of the floating diffusion portion FD, and outputs the amplified voltage. The row selecting transistor 107 connects the output terminal of the amplifying transistor 106 with the vertical output line 104 when the control voltage φSel becomes a high level, and outputs the voltage amplified by the amplifying transistor 106 to the vertical output line 104.

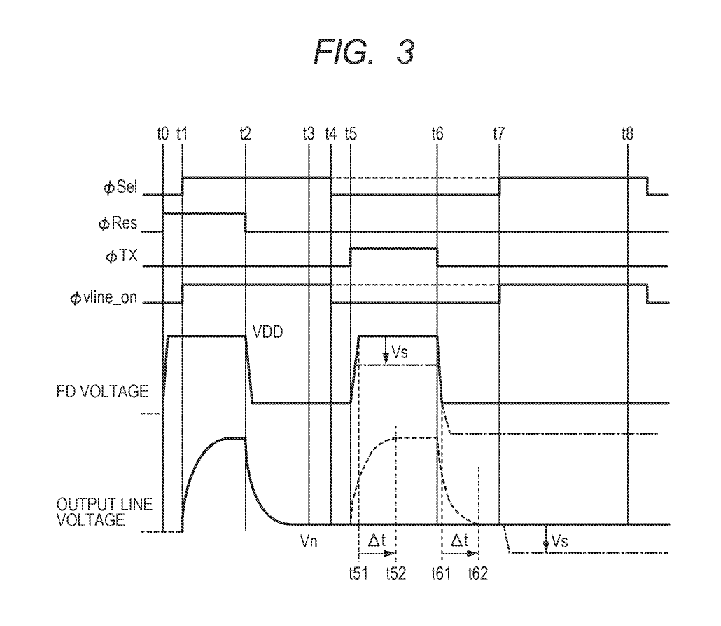

FIG. 3 is a timing chart illustrating a method for driving the solid-state imaging apparatus of FIG. 1. As for the potential of the floating diffusion portion FD, the potential at dark is shown by a solid line, and the potential at low luminance is shown by a chain line. In particular, the accuracy of the pixel signals at dark and at low luminance is important. Here, the period at dark shall mean the case where the electric charge due to the incident light is not generated in the photoelectric conversion portion 109. As for the pixel signal in this range, a noise originating in the circuit becomes more dominant than an optical shot noise. In addition, when a signal level has been emphasized by signal processing such as gamma processing or the noise has become a fixed pattern noise, the noise is emphasized even to several times with respect to a random noise and is easily perceived. Accordingly, the noise causes the lowering of an image quality.

In the present embodiment, before the electric charge of the photoelectric conversion portion 109 is read out, a noise signal Vn appearing after the floating diffusion portion FD has been reset is read out. Before the time t0, the potential of the floating diffusion portion FD is a residual potential corresponding to a residual charge. At the time t0, the control voltage φRes for the gate of the reset transistor 105 becomes a high level, and the reset transistor 105 is turned on. At this time, there exists a parasitic capacitance coupling between the gate of the reset transistor 105 and the floating diffusion portion FD. Thereby, a changing (hereinafter referred to as signal fluctuation) based on a value which is produced by dividing a transition voltage of the reset transistor 105 from a low level to a high level by the capacitance occurs in the potential of the floating diffusion portion FD. The parasitic capacitance of the floating diffusion portion FD is extremely small (usually, approximately several fF), and accordingly the change in the potential occurs in a short time period. Then, the floating diffusion portion FD is reset to the power source potential VDD.

At the time t1, the control voltage φSel for the gate of the row selecting transistor 107 in the row to be read out is set at a high level, and the row selecting switch 107 is turned on. In addition, at approximately the same timing, the control voltage φvline_on for the gate of the switch 102 also becomes a high level, and the switch 102 is turned on. Thereby, the amplifying transistor 106 works as a source follower together with the constant current source 103; and the amplifying transistor 106 amplifies the voltage of the floating diffusion portion FD, and outputs the amplified voltage to the vertical output line 104. The potential of the vertical output line 104 is charged to the potential according to the potential of the floating diffusion portion FD, but because the parasitic capacitance of the vertical output line 104 is as large as several pF or more, the signal waveform becomes a blunt waveform as in FIG. 3.

At the time t2, the reset of the floating diffusion portion FD is completed, the control voltage φRes is set at a low level, and the reset transistor 105 is turned off. At this time, the potential of the floating diffusion portion FD and the vertical output line 104 causes a signal fluctuation due to the parasitic capacitance coupling between the gate of the reset transistor 105 and the floating diffusion portion FD, similarly to the above description. Because the parasitic capacitance of the vertical output line 104 is large, the change in the potential of the vertical output line 104 needs a comparatively long time period before being settled, as is illustrated in FIG. 3. Here, voltage Vgs between the gate and source of the amplifying transistor 106 varies depending on the variation (ΔVth) of a threshold voltage Vth of the amplifying transistor 106 in each pixel 101, and accordingly each of the vertical output lines 104 has the potential variation of ΔVth. The potential of the floating diffusion portion FD converges to a noise signal. The noise signal Vn of the vertical output line 104 is supplied to the amplifier 131.

As a reference example, the waveforms of the potentials of the control voltages φSel and φvline_on and the vertical output line 104 in a period from the time t4 to the time t7 are shown by dashed lines. In the reference example, during the period from the time t4 to the time t7, the control voltages φSel and φvline_on are held at a high level. In a period from the time t5 to the time t6, the control voltage φTx for the gate of the transfer transistor 108 becomes a high level from a low level, the transfer transistor 108 becomes an ON state, and the electric charge in the photoelectric conversion portion 109 is transferred to the floating diffusion portion FD. The signal fluctuation of the floating diffusion portion FD due to the control voltage φTx at dark changes in an approximately similar way to the signal fluctuation caused by the control voltage φRes at the times t0 and t2. The potential of the floating diffusion portion FD shown by a solid line converges to a stable voltage at the times t51 and t61, and the potential of the vertical output line 104 converges at the times t52 and t62. Specifically, in the reference example, a rising convergence time t52 of the vertical output line 104 shown by a dashed line becomes later by Δt than the rising convergence time t51 of the floating diffusion portion FD shown by a solid line. Similarly, the falling convergence time t62 of the vertical output line 104 shown by a dashed line becomes later by Δt than the falling convergence time t61 of the floating diffusion portion FD shown by a solid line.

On the other hand, in the present embodiment, the solid-state imaging apparatus is driven so that a time period Δt is shortened which depends on this charging/discharging time constant. In order to suppress the signal fluctuation of the vertical output line 104 (or amplifier 131 which will be described later) due to the transition of the control voltage φTx for the gate of the transfer transistor 108, the control voltage φSel is set at a low level at the time t4 before the electric charge is transferred, and the row selecting transistor 107 is turned off. At the same time, the control voltage φvline_on for the gate of the switch 102 between the vertical output line 104 and the constant current source 103 is also set at a low level, and the switch 102 is turned off.

By the above described operation, the voltage VDD which is a power source that passes an electric current into the vertical output line 104 is separated by the row selecting transistor 107, and the constant current source 103 which extracts the electric current is separated by the switch 102. Thereby, the vertical output line 104 becomes a floating state, and accordingly the potential of the vertical output line 104 becomes a state shown by a solid line. At this time, each of the vertical output lines 104 shows the potential of the noise signal Vn until the time t7, due to the parasitic capacitance of the vertical output line 104. Incidentally, the noise signal Vn of the vertical output line 104 in every column has a variation component of ΔVn+ΔVth, and ΔVn is a variation component of the noise signal Vn. As has been described above, the initial potential of the vertical output line 104 after the time t4 becomes a value which is equal to the reset signal Vn.

Next, at the time t5, the control voltage φTx for the gate of the transfer transistor 108 becomes a high level, the transfer transistor 108 becomes an ON state, and the electric charge in the photoelectric conversion portion 109 is transferred to the floating diffusion portion FD. At the time t6, the control voltage φTx for the gate of the transfer transistor 108 becomes a low level, and the transfer transistor 108 is turned off. Next, at the time t7, the control voltage φSel for the gate of the row selecting transistor 107 and the control voltage φvline_on for the gate of the switch 102 become a high level, and the row selecting transistor 107 and the switch 102 are turned on. Thereby, the amplifying transistor 106 amplifies the voltage of the floating diffusion portion FD, and outputs a photo signal Vs+Vn shown by a chain line, to the vertical output line 104. The photo signal Vs is a signal based on a photoelectric charge. At the time t7, the potential of the vertical output line 104 starts the change of the photo signal Vs, according to the photoelectric charge shown by a chain line. In addition, as has been described above, there exists the capacitance coupling between the gate of the transfer transistor 108 and the floating diffusion portion FD. Thereby, when the control voltage φTx transits to a high level and a low level, the floating diffusion portion FD causes the changing of the potential according to the transition of the transfer transistor 108. However, in the period, the control voltage φSel for the gate of the row selecting transistor 107 is in a low level, and the vertical output line 104 and the amplifying transistor 106 are in an electrically non-conducting state. Because of this, the variation of the potential of the floating diffusion portion FD does not affect the potential of the vertical output line 104.

Thus, the previously described period Δt can be removed, and the speed for reading out the photo signal Vs can be increased. In addition, in the period at dark, a potential difference is not formed between the noise signal Vn and the signal at dark, and accordingly the noise signal Vn can be accurately removed by CDS processing of the amplifier 131 in the subsequent stage.

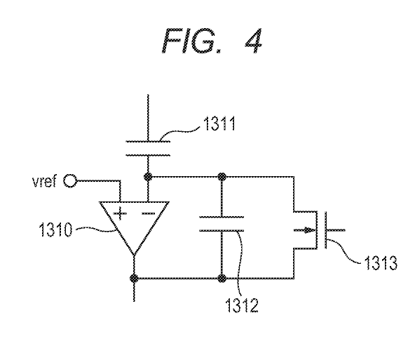

FIG. 4 is a circuit diagram illustrating a configuration example of the amplifier 131 in FIG. 1. The amplifier 131 has a differential amplifier 1310, a clamping capacitor 1311, a feedback capacitor 1312 and a reset switch 1313. A reference voltage vref is input into a positive input terminal of the differential amplifier 1310. The clamping capacitor 1311 is connected between the vertical output line 104 and a negative input terminal of the differential amplifier 1310. The differential amplifier 1310 inverts and amplifies the signal of the vertical output line 104, and outputs the inverted and amplified signal in a form of being superimposed on the reference voltage vref, to the line memory 141 in FIG. 1.

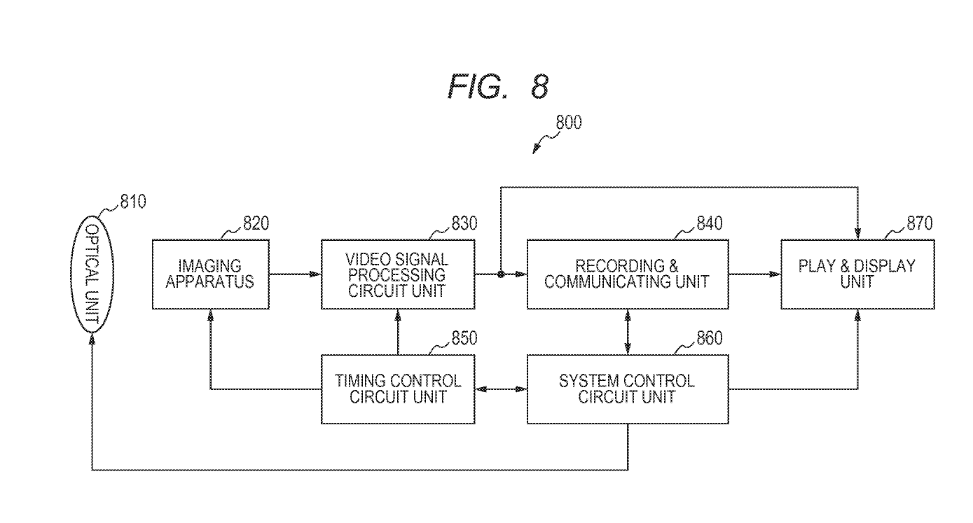

The amplifier 131 clamps the noise signal Vn of the vertical output line 104 appearing at the time t3, by the clamping capacitor 1311, and outputs an offset signal Vn′ of the amplifier 131. The offset signal Vn′ is stored in the line memory 141. Next, the amplifier 131 receives the photo signal Vs+Vn of the vertical output line 104 appearing at the time t7, and thereby outputs a photo signal Vs′=Vs+Vn′ in which the noise signal Vn is removed. At the time t8, the photo signal Vs' is stored in the line memory 141. The offset signal Vn′ and the photo signal Vs' which have been stored in the line memory 141 are successively read out column by column by the horizontal transferring circuit 142, a differential circuit (video signal processing circuit unit 830 in FIG. 8) provided in the subsequent stage subjects the read out signals to difference processing, and the photo signal Vs is obtained. As has been described above, the amplifier 131 is connected to the vertical output line 104, clamps the noise signal Vn, and outputs a signal according to the difference Vs between the photo signal Vs+Vn and the noise signal Vn.

As in the above way, an operation of reading out the signals of the pixels 101 is completed which are connected to the first row. After that, before the second row is read out, the amplifier 131 and the horizontal scanning circuit 143 are reset to the initial stage. In the following operations, similarly, the signals of the pixels 101 which are connected to the second row to the m-th row are successively read out by the signal sent from the vertical scanning circuit 11 that is controlled by the timing generator 12.

In the present embodiment, as is illustrated in FIG. 3, during a period t5 of a transition of the transfer transistor 108 from an OFF state to an ON state and during a period t6 of a transition of the transfer transistor 108 from the ON state to the OFF state, the selecting transistor 107 and the switch 102 are in the OFF state. In a period between t5 and t6, during which the transfer transistor 108 is in the ON state, the selecting transistor 107 and the switch 102 can be in the OFF state. The selecting transistor 107 and the switch 102 are turned on at the time t7 after the time t6 at which the transfer transistor 108 has been turned to the OFF state.

At the time t3, in the state in which the floating diffusion portion FD is reset, the selecting transistor 107 and the switch 102 become the ON state, and the noise signal Vn is output to the vertical output line 104. Subsequently, at the time t4, the selecting transistor 107 and the switch 102 are turned off. Subsequently, at the time t5, the transfer transistor 108 is turned on. After that, at the time t6, the transfer transistor 108 is turned off. After that, at the time t7, the selecting transistor 107 and the switch 102 become the ON state, and the photo signal Vs+Vn is output to the vertical output line 104.

### Second Embodiment

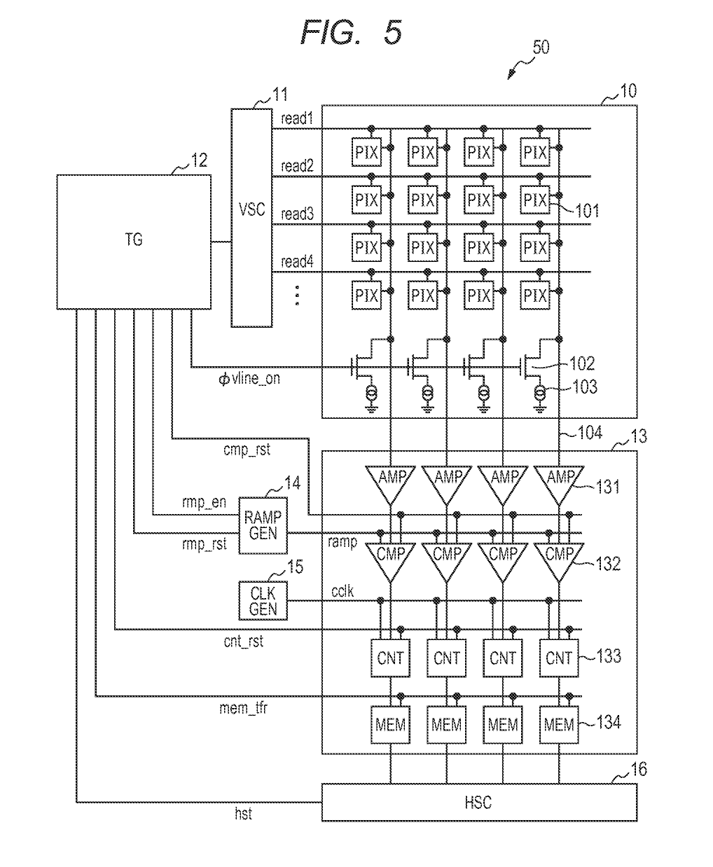

FIG. 5 is a view illustrating a configuration example of a solid-state imaging apparatus according to a second embodiment of the present invention. A column circuit 13 converts analog signals into digital signals. Hereafter, a point will be described at which the present embodiment is different from the first embodiment. The pixel array 10, the vertical scanning circuit 11 and the amplifier 131 are similar to those in the first embodiment. A ramp signal generator 14 generates a ramp signal ramp according to control signals rmp_en and rmp_rst of the timing generator 12. At the timing at which the generation of the ramp signal ramp is started, a counter 133 in each of the columns resets a count value according to a reset signal cnt_rst of the timing generator 12, and after that, the counter 133 counts a clock signal cclk which has been generated by a clock generator 15. A comparator 132 in each of the columns compares the output signals of the amplifiers 131 in each of the columns with the ramp signals ramp in each of the columns, respectively. Incidentally, in the comparator 132, it is omitted to illustrate clamping capacitors of an input terminal for a signal of the amplifier 131 and an input terminal for the ramp signal ramp, and a clamp switch to a reference potential. At a timing at which the ramp signal ramp has become larger than the output signal of the amplifier 131, the output signal of the comparator 132 is inverted, and the counter 133 stops a counting operation. After that, the memories 134 in each of the columns store the count values of the counters 133 in each of the columns therein according to a control signal mem_tfr of the timing generator 12, respectively. After that, the horizontal scanning circuit 16 successively selects the memories 134 in each of the columns, and reads out the count values stored in the memories 134 in each of the columns, as a pixel signal.

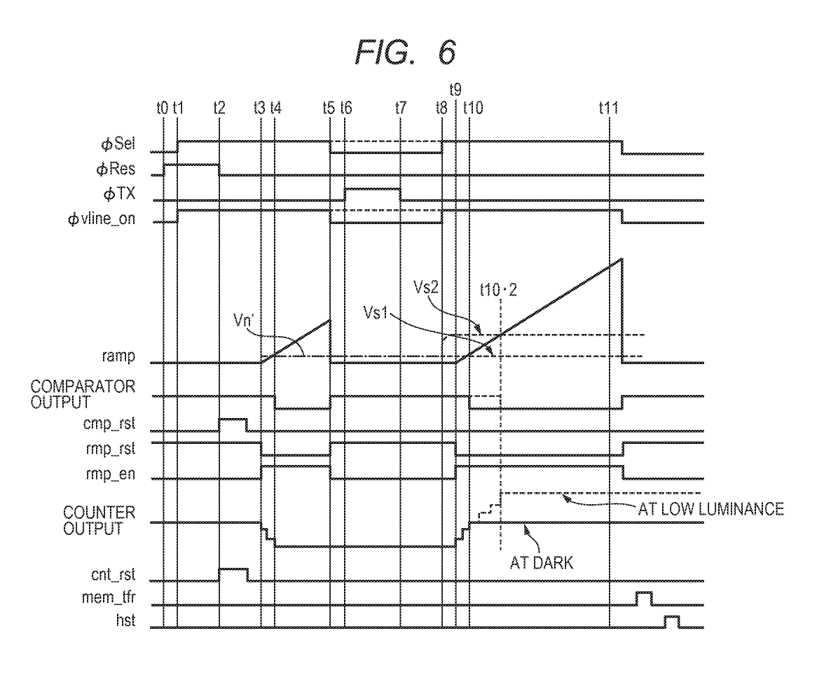

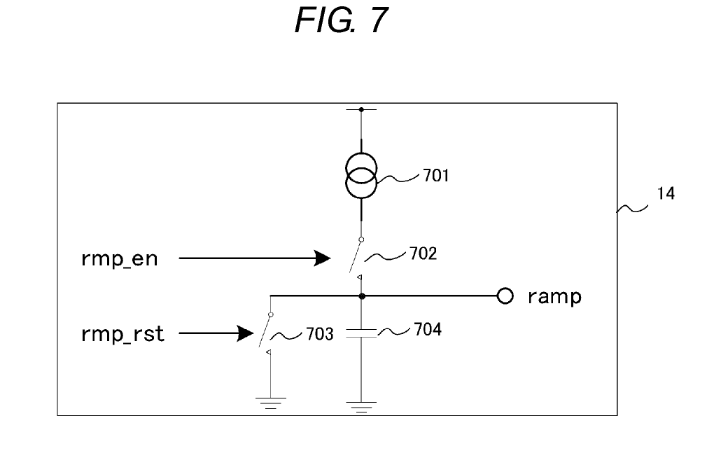

FIG. 7 is a circuit diagram illustrating a configuration example of the ramp signal generator 14 in FIG. 5. A series-connected circuit of a current source 701 and a switch 702 is connected between a power-source potential node and the output terminal of the ramp signal ramp. A switch 703 is connected between the output terminal of the ramp signal ramp and a ground potential node. A capacitor 704 is connected between the output terminal of the ramp signal ramp and a ground potential node. The switch 702 is OFF/OFF controlled by a control signal rmp_en. The switch 703 is OFF/OFF controlled by the control signal rmp_rst. The ramp signal generator 14 generates a ramp signal (reference signal) ramp that changes as a time elapses, which is illustrated in FIG. 6.

FIG. 6 is a timing chart illustrating a method for driving the solid-state imaging apparatus of FIG. 5. The control voltages φSel, φRes, φTx and φvline_on are the same as those in FIG. 3. The offset signal Vn′ is a signal output from the amplifier 131 in a period between the times t3 and t8. Photo signals Vs1 and Vs2 are signals output from the amplifier 131 after the time t9. A photo signal Vs1 is a signal at dark, and a photo signal Vs2 is a signal at low luminance. The photo signal Vs1 at dark has the same potential as that of the offset signal Vn′.

At the time t2, the comparator 132 and the counter 133 are reset by the reset signals cmp_rst and cnt_rst. At the time t3, the ramp signal generator 14 turns the reset switch 703 to the OFF state, and turns on the charging switch 702, according to the reset signals rmp_rst and rmp_en. When the charging switch 702 is turned on, a constant current flows into the capacitor 704 from the current source 701, and the capacitor 704 is charged. The ramp signal ramp forms a potential waveform in which the rate changing with time has a constant gradient. The counter 133 starts down-counting from the generation starting time t3 of the ramp signal rmp.

In a period between the times t3 and t5, the comparator 132 compares the offset signal Vn′ with the ramp signal ramp. At the time t4, when the ramp signal ramp becomes larger than the offset signal Vn′, the output signal of the comparator 132 is inverted from a high level to a low level. Then, the counter 133 stops down-counting, and holds the count value. Specifically, the counter 133 performs the down-counting operation from the ramp signal generation starting time t3 until the output signal inversion time t4 of the comparator 132.

Next, at the time t5, after the analog to digital conversion of the offset signals Vn′ in all of the columns has been finished, the signal rmp_rst is set at a high level, the signal rmp_en is set at a low level, and the ramp signal ramp is reset to the ground potential. Thereby, the output signal of the comparator 132 is returned from a low level to a high level.

Next, the analog to digital conversion of the photo signal Vs1 or Vs2 will be described below. At the time t8, the photo signal Vs1 or Vs2 is output to the vertical output line 104. At the time t9, the ramp signal generator 14 turns the reset switch 703 to the OFF state and turns on the charging switch 702, according to the reset signals rmp_rst and rmp_en. When the charging switch 702 is turned on, a constant current flows into the capacitor 704 from the current source 701, and the capacitor 704 is charged. The ramp signal ramp forms a potential waveform in which the rate changing with time has a constant gradient. The counter 133 starts up-counting from the generation starting time t9 of the ramp signal rmp.

After the time t9, the comparator 132 compares the photo signal Vs1 or Vs2 with the ramp signal ramp. In the case of the photo signal Vs1 at dark, when the ramp signal ramp becomes larger than the photo signal Vs1 at the time t10, the output signal of the comparator 132 is inverted from a high level to a low level. Then, the counter 133 stops the up-counting, and holds the count value. Specifically, the counter 133 performs the up-counting operation from the ramp signal generation starting time t9 until the output signal inversion time t10 of the comparator 132. At this time, the counter value of the counter 133 is zero, because the offset signal Vn′ and the photo signal Vs1 have the same potential. This count value is a value obtained by subtracting the offset signal Vn′ from the photo signal Vs1, and becomes a pixel signal in which the offset has been removed from the photo signal.

In the case of the photo signal Vs2 at low luminance, when the ramp signal ramp becomes larger than the photo signal Vs2 at the time t10-2, the output signal of the comparator 132 is inverted from a high level to a low level. Then, the counter 133 stops the up-counting, and holds the count value. Specifically, the counter 133 performs the up-counting operation from the ramp signal generation starting time t9 until the output signal inversion time t10-2 of the comparator 132. At this time, the counter value of the counter 133 is a value obtained by subtracting the offset signal Vn′ from the photo signal Vs2, and becomes a pixel signal in which the offset has been removed from the photo signal.

In the A/D conversion method that has been described in the present embodiment and uses the ramp signal in which the signal level monotonically changes with respect to the time period, as the signal level of the analog signal is lower, the digital value is determined in a shorter time period. For this reason, it is particularly effective to reduce an influence of a signal fluctuation originating in the operation of the transfer transistor and the reset transistor.

As has been described above, the solid-state imaging apparatus according to the present embodiment prevents the variation of the vertical output line 104 due to the signal fluctuation originating in the capacitance coupling between the gate of the transfer transistor 108 and the floating diffusion portion FD. Because the solid-state imaging apparatus can make the offset signal Vn′ held at the output terminal of the amplifier 131 until the photo signal is read out, the solid-state imaging apparatus can suppress an offset noise at dark or at low luminance even when having performed an analog-to-digital-conversion processing, and simultaneously can achieve reading out at high speed.

In each of the above described embodiments, the case has been described where the signals φSel and φvline_on are in a high level during a period between the times t1 and t2, but these signals may be set at a low level.

### Third Embodiment

FIG. 8 is a view illustrating a configuration example of an imaging system according to a third embodiment of the present invention. An imaging system 800 includes, for instance, an optical unit 810, an imaging apparatus 820, a video signal processing circuit unit 830, a recording & communicating unit 840, a timing control circuit unit 850, a system control circuit unit 860, and a play & display unit 870. The imaging apparatus 820 is the solid-state imaging apparatus of the first and second embodiments.

The optical unit 810 that is an optical system such as a lens focuses an image of light emitted from an object onto an pixel array 10 of the imaging apparatus 820, in which a plurality of pixels 101 are two-dimensionally arrayed, and forms an image of the object on the pixel array 10. The imaging apparatus 820 outputs signals according to the light of which the image has been focused on the pixel array 10, on the timing based on the signal output from the timing control circuit unit 850. The signals output from the imaging apparatus 820 are input into the video signal processing circuit unit 830 that is a video signal processing unit, and the video signal processing circuit unit 830 performs signal processing with a specified method by a program or the like. The signals obtained by the processing in the video signal processing circuit unit 830 are sent to the recording & communicating unit 840 as image data. The recording & communicating unit 840 sends signals for forming an image to the play & display unit 870, and makes the play & display unit 870 play & display a moving image or a still image. The recording & communicating unit 840 also communicates with the system control circuit unit 860 by receiving the signals sent from the video signal processing circuit unit 830, and also performs an operation of recording the signals for forming an image on an unillustrated recording medium.

The system control circuit unit 860 is a unit for collectively controlling an operation of the imaging system, and controls a drive of each of the optical unit 810, the timing control circuit unit 850, the recording & communicating unit 840, and the play & display unit 870. In addition, the system control circuit unit 860 is provided, for instance, with an unillustrated storage unit that is a recording medium, and records a program and the like which are necessary for controlling the operation of the imaging system, in the storage unit. The system control circuit unit 860 also supplies, for instance, a signal which switches driving modes according to an operation of a user, into the imaging system. Specific examples include: a signal for a change of a row to be read or a row to be reset; a signal for a change of an angle of view, which accompanies an operation of an electronic zoom; and a signal for a shift of an angle of view, which accompanies electronic vibration control. The timing control circuit unit 850 controls the driving timings for the imaging apparatus 820 and the video signal processing circuit unit 830 based on the control by the system control circuit unit 860.

Note that the above embodiments are merely examples how the present invention can be practiced, and the technical scope of the present invention should not be restrictedly interpreted by the embodiments. In other words, the present invention can be practiced in various ways without departing from the technical concept or main features of the invention.

According to each of the above described embodiments, the solid-state imaging apparatus can suppress the lowering of the noise reduction rate while increasing the speed of readout.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2013-191038, filed Sep. 13, 2013, which is hereby incorporated by reference herein in its entirety.

What is claimed is:

1. A solid-state imaging apparatus comprising:
a photoelectric conversion portion configured to converting light into an electric charge;
a floating diffusion portion configured to convert the electric charge into a voltage;
a transfer transistor configured to transfer the electric charge converted by the photoelectric conversion portion to the floating diffusion portion;
an amplifying transistor configured to amplify the voltage of the floating diffusion portion;
a selecting transistor configured to output the voltage amplified by the amplifying transistor to an output line; and
a switch provided between the output line and a current source, wherein
the selecting transistor and the switch are held at an OFF state, during a period of a transition of the transfer transistor from an OFF state to an ON state, and during a period of a transition of the transfer transistor from the ON state to the OFF state.

2. The solid-state imaging apparatus according to claim 1, wherein
the selecting transistor and the switch are at an OFF state, during a period of the OFF state of the transfer transistor.

3. The solid-state imaging apparatus according to claim 2, wherein
the selecting transistor and the switch are turned ON, after turning OFF of the transfer transistor.

4. The solid-state imaging apparatus according to claim 1, wherein,
under a condition of resetting the floating diffusion portion, the selecting transistor and the switch are turned ON, to output a noise to the output line,
thereafter, the selecting transistor and the switch are turned OFF,
thereafter, the transfer transistor is turned ON,
thereafter, the transfer transistor is turned OFF,
thereafter, the selecting transistor and the switch are turned ON, to output a photo signal to the output line.

5. The solid-state imaging apparatus according to claim 4, further comprising
an amplifier being connected to the output line, clamping the noise signal, and outputting a signal according to a difference between the photo signal and the noise signal.

6. The solid-state imaging apparatus according to claim 5, further comprising
a comparator configured to compare an output signal from the amplifier and a reference signal changing as a time elapses, and
a counter counting until inversion of an output signal of the comparator.

7. An imaging system comprising:
the solid-state imaging apparatus according to claim 1; and
an optical unit configured to focus an image of light onto the solid-state imaging apparatus.

8. A driving method of a solid-state imaging apparatus comprising:
a photoelectric conversion portion configured to converting light into an electric charge;
a floating diffusion portion configured to convert the electric charge into a voltage;
a transfer transistor configured to transfer the electric charge converted by the photoelectric conversion portion to the floating diffusion portion;
an amplifying transistor configured to amplify the voltage of the floating diffusion portion;
a selecting transistor configured to output the voltage amplified by the amplifying transistor to an output line; and
a switch provided between the output line and a current source, wherein the method comprising:
holding the selecting transistor and the switch at an OFF state, during a period of a transition of the transfer transistor from an OFF state to an ON state, and during a period of a transition of the transfer transistor from the ON state to the OFF state.
